(19) United States
(12) Patent Application Publication
(10) Pub. No.: US 2004/0114702 A1
(43) Pub. Date: Jun. 17, 2004

(54) Bang-bang phase detector for full-rate and half-rate schemes clock and data recovery and method therefor

(75) Inventors: Daniel J. Friedman, Sleepy Hollow, NY (US); Mounir Meghelli, Tarrytown, NY (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY

(21) Appl. No.: 10/317,174

(22) Filed: Dec. 12, 2002

(51) Int. Cl. H03D 3/24

(52) U.S. Cl. 375/373

(57) ABSTRACT

A phase detector (and method therefor), includes a first flip-flop for sampling an incoming data signal in accordance with a first local clock signal to produce a first sampled data signal, a second flip-flop for sampling the incoming data signal in accordance with a second local clock signal to produce a second sampled data signal, and a third flip-flop for sampling the second sampled data signal, as based on the first sampled data signal, to produce a binary control signal. The third flip-flop comprises a double-edge flip-flop.

### CROSS-REFERENCE TO RELATED APPLICATIONS

The present Application is related to the following co-pending application:

U.S. patent application Ser. No. 09/435,838, “Binary Self-Correcting Phase Detector for Clock and Data Recovery”, filed on Nov. 8, 1999, having IBM Docket YOR999-402, assigned to the present assignee and incorporated herein by reference.

### BACKGROUND OF THE INVENTION

1. Field of the Invention

The present invention generally relates to data transmission and communication systems, and more particularly to tri-state phase detectors used in a clock recovery system for recovering a clock signal from transmitted NRZ (non-return-to-zero) random data. The phase detector of the present invention provides the retimed or regenerated data directly from the transmitted NRZ data utilizing the recovered clock signal. The phase detector concept of the present invention can be used either to recover a full-rate clock or a half-rate clock.

2. Description of the Related Art

When data are transmitted over a communication link, the associated clock signal is generally not transmitted, thereby providing for better efficiency of the link. However, the clock signal is necessary to retime or regenerate the received data which is typically corrupted by noise due to the physical medium and electronic and/or optical devices in the case of a transmission over an optical (e.g., glass) fiber. The clock signal also provides timing necessary for subsequent digital circuitry such as demultiplexers or framers. Therefore, transmission systems generally require that the clock signal at the receiving end of the link somehow be extracted from the incoming data signal.

In the conventional systems, two main techniques are usually used for clock recovery. These two approaches are direct extraction techniques and phase-locked loop (PLL) techniques.

In a direct extraction scheme, a high Q bandpass filter is required, among other circuits. However, these high Q bandpass filters are generally expensive and limit the link to work only at a single data rate. Also, direct extraction techniques are difficult to integrate therein. In that case, phase shifters are used to ensure adequate alignment between the extracted clock and the received data. This alignment is temperature- and process-dependent and will vary depending on the circuitry used.

In PLL techniques, a reference clock is generated at the frequency or sub-frequencies of the received data rate, usually using a voltage-controlled oscillator (VCO). A phase detector (PD) circuit compares the phase angle between the VCO clock signal and the received data stream. The phase detector provides a control signal which is a function of the relative phase between the VCO clock signal and the received data signal. This control signal is used to adjust the VCO frequency until the clock signal is synchronized with the received data.

The PD is a key circuit for clock and data recovery applications using PLL techniques, especially when the timing becomes critical as the data rate increases. As frequencies become higher, time delays inherent in digital circuits become more significant compared to the bit interval. The bit error rate (BER) of a transmission system (e.g., a measure of the number of erroneous data bits received divided by the total number of data bits received in a specified transmission time) is very dependent on the quality of the extracted clock, and also on how well the extracted clock signal is aligned with the received data. To ensure optimum bit error rate when sampling the received data with the extracted clock for data regeneration, it is desirable to sample at the midpoint of each bit interval. At very high clock frequencies (e.g., a few GHz to tens of GHz), a misalignment of even a few picoseconds between clock and data can dramatically increase the transmission system's bit error rate.

Two main classes of PD circuits, linear PDs and binary PDs, are commonly used in clock and data recovery applications. Linear PDs may not work well at extremely high bit rates because they must generate relatively narrow pulses compared to the bit interval as the phase error becomes smaller. Also, the static phase error of the data recovery loop using a linear PD may be relatively large, because of unbalanced loading and delay mismatch for example, which is not desirable for optimum sampling of the received data. Binary PDs, also known as “bang-bang” PDs or “early/late” PDs are able to operate at higher frequencies (e.g., at the maximum clock frequency of a data latch) and can generate a much smaller static phase error as compared to linear PDs.

A desirable feature is to have the retiming of the data function as part of the PD operation itself. In this case, no external adjustment of the clock and data alignment is required to accommodate process, temperature and power supply variation and aging as well, since the PLL will act in such a way that the clock will stay aligned with the data.

Another desirable feature is to enable a high impedance state, or a tri-state output, indicating that transitions are missing in the received random data stream. This high impedance state will minimize VCO frequency drift by holding its frequency control input voltage constant during periods of missing transitions in the incoming data stream. In turn, this will reduce the jitter generation (or phase noise) due to VCO frequency drift and will help prevent unlocking of the PLL. These PDs are known as “tri-state phase detectors”.

For very high transmission data rates in particular, complex data and clock distribution should be avoided. Indeed, a high data and/or clock loading and a complex physical design may significantly degrade the circuit performance. The parasitic elements associated with interconnect wires cause loading and coupling effects that degrade the frequency behavior and the noise performance of the circuits.

A further PD parameter that is critical for PLL performance is “latency” (e.g., the input to output propagation delay of the PD). Latency has a direct impact on the jitter generation of a PLL, and should be as small as possible to reduce output jitter.

Finally, because transmission data rates are increasing rapidly, PLL circuits using VCOs running at a sub-harmonic of the data rate are often used to enable application of existing technologies with limited frequency performance. A half-rate VCO, which runs at a frequency equal to half the data rate, is often chosen as it represents a good compromise between performance and complexity as opposed to a full-rate VCO, which runs at a frequency equal to the data rate. A versatile PD that can be used either with a full-rate VCO or a half-rate VCO without a major increase in its complexity is then highly desirable.

In summary, it is highly desirable that PDs used for clock and data recovery applications have the following features:

1) Bang-bang (or early/late) type of operation, thus enabling higher operating frequency and a smaller static phase error (as opposed to linear PDs);

2) Self-correcting operation to accommodate process, temperature and power supply variation and aging as well;

3) Retiming function as part of its operation for optimum clock and data alignment;

4) Tri-state output to accommodate long run length random data to enable robust locking behavior and reduced jitter generation;

5) Short latency to reduce the jitter generation;

6) Very simple architecture to minimize power consumption, enable straightforward data and clock distribution, and enable a compact layout design, with the latter two features required to achieve high speed operation.

7) A versatile architecture that can be easily adapted for full-rate and half-rate clocking without a major increase in either complexity or power consumption.

One very common full-rate bang-bang tri-state PD is described by J. D. H Alexander in “Clock Recovery From Random Binary Signals”, as archived in the journal Electronics Letters (volume 11, pages 541-542, October 1975). In this approach, three samples of the data are taken using data latches: two successive data samples and one sample in between. The PD output signal is generated by comparing these samples using logic gates. For that approach, a minimum of 4 logic gates plus 8 data latches are required. Therefore, the total gate count is 12, with the clock being distributed to 8 data latches. The propagation delay of this PD is equal to 1 clock cycle plus 3 gate delays.

A half-rate bang-bang tri-state phase detector is described by M. Reinhold et al. in “A fully integrated 40-Gb/s clock and data recovery IC with 1:4 demux in SiGe technology”, as reported in the IEEE Journal of Solid-State Circuits (volume 36, number 12, pages 1937-1944, December 2001). The present authors have used the concept of the full-rate PD described above modified for half-rate operation.

### SUMMARY OF THE INVENTION

Simple and efficient PDs such as the one described in the present invention, having all the seven features listed above, have significant advantage, especially when targeting high transmission data rates.

The present invention, which addresses the needs identified in the conventional techniques, provides an efficient tri-state PD having a bang-bang type of operation preferably used for clock and data recovery applications. Since the data recovery function is part of its operation, this PD has a self-correcting clock and data alignment, which maintains sampling at the optimum sampling point regardless of process fabrication spread or power supply and temperature variations. The concept of this PD is an extension of the one described in the above-listed copending application, which is hereby incorporated herein by reference.

In comparison to the Alexander full-rate bang-bang tri-state PD mentioned above, the full-rate PD version of the present invention requires a minimum total gate count of 9 (8 data latches and one XOR gate), with the clock signal being distributed to 6 data latches only. Considering that all the logic gates dissipate the same power, this is a 25% power consumption and clock loading reduction from the Alexander design. The propagation delay can be as low as 1 clock cycle plus 2 gate delays. If the gate delay is equal to half a clock cycle, then the propagation delay reduction is 20%.

The Reinhold PD described above uses 16 data latches and 10 logic gates with a clock loading of 10 data latches. Its propagation delay is at least equal to 1 clock cycle plus 4 gate delays. In comparison, the half-rate PD version of the present invention requires a total gate count of 12 with a clock loading of 5 data latches. Considering that all the logic gates dissipate the same power, this is more than 53% power consumption saving and 50% clock loading reduction. The propagation delay is reduced to half a clock cycle and 2 gate delays. If the gate delay is equal to half a clock cycle, then the propagation delay reduction is 50%.

In a first embodiment of the invention, the PD includes a first and second Edge-Triggered Data Flip-Flop (ETDFF) for sampling an incoming data stream with a first and second clock signal, respectively, to produce a first and second sampled data signal, respectively. A third ETDFF is used to sample the first sampled data signal with the first clock signal to produce a third sampled data signal. A Modified Double-Edge-Triggered Data Flip-Flop (M-DETDFF) is used to sample the second sampled data signal with the first sampled data signal. The M-DETDFF operates similarly to a classical double-edge-triggered data flip-flop which transfers its input to its output on each transition of the sampling signal. However, in contrast to the classical double-edge-triggered data flip-flop, the M-DETDFF alternatively transfers its input to its output on one sampling edge, and the complement of its input to its output on the other sampling edge.

The PD of the present invention is optimized to be used for clock and data recovery using the phase-locked loop (PLL) technique. The incoming data stream is preferably Non-Return-to-Zero (NRZ) coded. The first and second clock signals have the same frequency and the first clock signal is half a bit (of the incoming data stream) time earlier than the second clock signal.

The first and second sampled signals are identical, but are shifted from one another by half a bit time. The sign of this shift depends on the position of the first and second clock edges (e.g., the edges used to sample the incoming data stream) with respect to the edges of the incoming data stream. Because the second sampled signal is sampled using the first sampled signal, the M-DETDFF output is thus a binary signal (or a bang-bang signal) which state indicates whether the incoming data stream is leading or lagging the clock signal.

The incoming data stream may include long series of consecutive identical bits, in which case the output of the M-DETDFF is not valid anymore since it continues to hold its previous state in the absence of transitions. Consequently, a transition detector is required. The first and third sampled signals are taken from the incoming data stream, with the third sampled signal one bit time ahead of the first sampled signal. Consequently, the first and third sampled signals will be different each time a transition occurs in the incoming data stream. Thus, an XOR gate applied to the first and third sampled signals can be used to sense the presence of data transitions.

The output of the XOR gate and the output of the M-DETDFF can be combined, if required, to form a single signal having three different states: one indicating that the incoming data stream is leading the second clock signal; one indicating that the incoming data stream is lagging the second clock signal; and one indicating that the incoming data stream has a missing transition. A PD that produces this kind of output information is known as a tri-state PD. The propagation delay of the XOR gate should closely match the clock to data output propagation delay of the M-DETDFF in order to synchronize the data transition detection with the phase comparison.

In a second embodiment of the invention, instead of using a XOR gate as a transition detector, the first and third sampled signals are subtracted from each other and the resulting fourth sampled signal, instead of the first sampled signal, is used to sample the second sampled signal. Consequently, each time transitions in the incoming data stream are present, the fourth sampled signal will toggle between two states. When a transition in the incoming data stream is missing, the value of the fourth sampled signal is zero, and will remain zero until the next transition happens. Thus, when transitions in the incoming data stream are present, the M-DETDFF operates as in the first embodiment. When a transition in the incoming data stream is missing, the M-DETDFF output becomes zero. If differential architecture is used to implement the PD, then no additional gate is required to subtract the first and third sampled signals since the complementary signals are readily available.

The PD of the present invention can be used either as a full-rate PD or a half-rate PD. When a full-rate PD is required, then the first, second and third ETDFFs preferably are all single edge-triggered data flip-flops. When a half-rate PD is required, then the first, second and third ETDFFs preferably are all double edge-triggered data flip-flops.

When the present invention is used for clock and data recovery using the phase-locked loop technique, then under locked conditions, the sampling edges of the second clock signal are automatically aligned with the edges of incoming data stream. Thus, the sampling edges of the first clock signal are automatically aligned at the middle of each data bit of the incoming data stream, and thus the first and third sampled signals correspond to the recovered (or regenerated) data. Thus, the data recovery is fully part of the PD operation and the optimum sampling point is automatically maintained regardless of technology process spread or power supply and temperature variations. Such PDs are known as “self-correcting PDs”.

The PD of the present invention has a simple architecture with a low gate count. This in turn reduces the physical implementation complexity. Moreover, the clock and data loading is low. Also, the latency of the PD of the present invention is reduced as a result of the low gate count. These features make the PD very well adapted for high data rate operation (a few Gb/s to tens of Gb/s) in particular.

To achieve the above, in a first aspect of the present invention, a phase detector (and a method), includes a first flip-flop for sampling an incoming data signal in accordance with a first local clock signal to produce a first sampled data signal, a second flip-flop for sampling the incoming data signal in accordance with a second local clock signal to produce a second sampled data signal, and a third flip-flop for sampling the second sampled data signal, as based on the first sampled data signal, to produce a binary control signal. The third flip-flop preferably includes a double-edge flip-flop.

In a second aspect of the present invention, a circuit for regenerating a data signal and/or recovering a clock signal, includes a first means for calculating a transition detection of an input data signal and a second means for calculating an early/late control signal, where the second means includes a modified double-edge-triggered flip-flop, the modified double-edge-triggered flip-flop comprising a flip-flop in which an output on a first sampling edge equals an input into the flip-flop at the time of the first sampling edge and the output on a next sampling edge equals a complement of an input into the flip-flop at the time of the second sampling edge.

### BRIEF DESCRIPTION OF THE DRAWINGS

The foregoing and other purposes, aspects and advantages will be better understood from the following detailed description of preferred embodiments of the invention with reference to the drawings, in which:

FIG. 1 is a block diagram of a PD 100 according to a first embodiment of the present invention;

FIG. 2A is a block diagram of a PD 200 according to a second embodiment of the present invention;

FIG. 2B is a table summarizing the subtraction characteristic of the second embodiment of the present invention;

FIG. 3 is an example of a block diagram of a Double-Edge-Triggered Data Flip-Flop (DETDFF);

FIG. 4 is an example of a block diagram of a Modified Double-Edge-Triggered Data Flip-Flop (M-DETDFF); and

FIG. 5 is a block diagram of a half-rate PD 500 according to a third embodiment of the present invention.

### DETAILED DESCRIPTION OF PREFERRED EMBODIMENTS OF THE INVENTION

First Embodiment

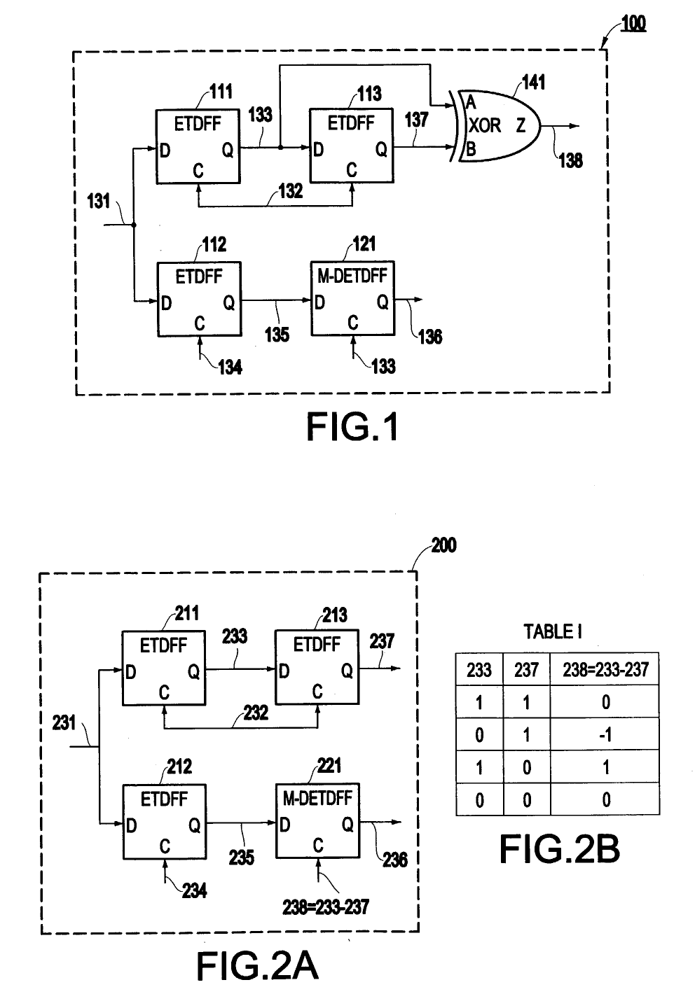

Referring now to the drawings, FIG. 1 illustrates the structure of a PD 100 according to a first embodiment of the present invention. The PD 100 includes a plurality (e.g., preferably three) of Edge-Triggered Data Flip-Flops (ETDFF) 111, 112 and 113, an XOR gate 141, and a Modified Double-Edge-Triggered Data Flip-Flop (M-DETDFF) 121.

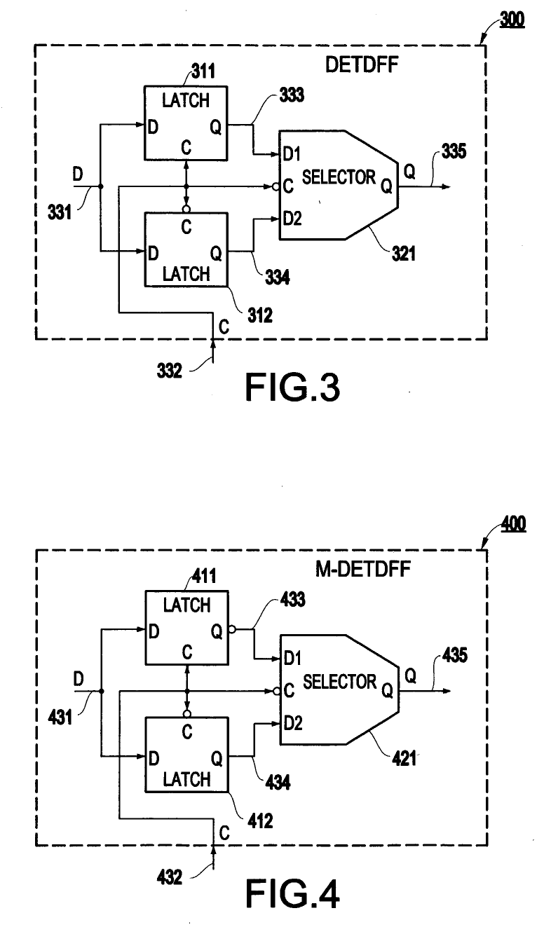

M-DETDFF 121 operates in a similar way as a classical double-edge-triggered data flip-flop which transfers its input to its output on each transition of the sampling signal. Instead of transferring its input on each sampling edge, however, the M-DETDFF 121 alternatively transfers its input to its output on one sampling edge, and the complement of its input to its output on the other sampling edge. An example of such a circuit is given in FIG. 3 and described later below.

A signal 131 is received in the input D of a first ETDFF 111 and in the input D of a second ETDFF 112. A first clock signal 132 is applied to the clock input C of the first ETDFF 111, thereby sampling the signal 131. A second clock signal 134 is applied to the clock input C of the second ETDFF 112, thereby sampling the signal 131. The signal 133 present at the output Q of the first ETDFF 111 is applied to the input D of a third ETDFF 113. The first clock signal 132 is also applied to the clock input C of the third ETDFF 113, thereby sampling the signal 133.

The signal 135 present at the output Q of the second ETDFF 112 is applied to the input D of a M-DETDFF 121. The signal 133 present at the output Q of the first ETDFF 111 is also applied to the clock input C of the M-DETDFF 121, thereby sampling the signal 135. The signal 133 present at the output Q of the first ETDFF 111 is also applied to the input A of a XOR gate 141. The signal 137 present at the output Q of the second ETDFF 112 is applied to the input B of the XOR gate 141.

PD 100 is optimized to be preferably used in a receiver of a transmission system to recover the clock signals 132 and 134 from the signal 131 using the phase-locked loop technique. The signal 131 is in this case a random data stream. In the rest of the description, the signal 131 refers to a random data stream which is preferably NRZ (Non-Return-to-Zero) coded and will be referred to as data 131. It is noted that PD 100 is optimized if the clock signals 132 and 134 have preferably exactly the same frequency, the clock signal 134 being preferably half a data 131 bit time late compared to the clock signal 132. The data 131 bit time preferably is equal to half of the smallest period presents in the signal. The rate of data 131 preferably is equal to the inverse of a bit time.

It is also noted that PD 100, when used for clock recovery applications from NRZ random data, is optimized with either the frequency of the clock signals 132 and 134 equal to the rate of data 131 or the frequency of the clock 132 and 134 equal to half the rate of data 131.

When the frequency of the clock signals 132 and 134 is to be equal to the rate of the data 131, then the following conditions should apply: ETDFFs 111, 112 and 113 are preferably single-edge triggered data flip-flops, e.g., all of them are triggered only on either positive or negative edges of the clock signals 132 and 134, respectively. PD 100 is then known as a “full-rate PD”. When the frequency of the clock signals 132 and 134 is to be equal to half the rate of data 131, then the following conditions should apply: ETDFFs 111, 112 and 113 preferably are double-edge triggered data flip-flop, e.g., all of them are triggered on both positive and negative edges of the clock signals 132 and 134, respectively. PD 100 is then known as a “half-rate PD”.

The signals 133 and 135 are samples of the data 131 shifted from one another by half a bit time in one or the other direction depending on the position of the sampling edges (e.g., the edges used to trigger ETDFF 112) of the clock signal 134 with respect to the edges of the data 131. The M-DETDFF 121 senses the sign of this shift (e.g., the M-DETDFF will sense if the signal 133 is leading or lagging the signal 135). Indeed, the M-DETDFF 121 transfers the signal 135 to its output Q, which is the signal 136, on one edge of the signal 133 and the complement of the signal 135 to its output Q, which is the signal 136, on the other edge of the signal 133. Thus, the signal 136 present at the output Q of the M-DETDFF 121 is a binary signal which state indicates whether the clock signal 134 is leading or lagging the data 131.

When the PD 100 is used for clock and data recovery applications using the phase-locked loop technique, then under locked conditions, the edges of the clock 134 which are used to trigger the ETDFF 112 are aligned with the edges of the data 131. Consequently, the edges of the clock 132 which are used to trigger the ETDFF 111 and ETDFF 113 are aligned at the midpoint of each bit interval of the data 131 and the data 131 can thus be recovered.

In addition to the binary signal 136, which state indicates whether data 131 is leading or lagging the clock signal 134, an indication is preferably required when long series of consecutive identical bits are present in the data 131. Indeed, when a transition is missing, the output 136 is not updated and will remain the same until the next transition happens. Consequently, the output 136 is not a valid indication of the phase relationship between the clock signal 134 and the data 131 when transitions are missing. But, since the signal 137 present at the output Q of ETDFF 113 is identical to the signal 133 (but ahead in time by one bit time), the binary signal 138 present at the output Z of the XOR gate 141 is then a data transition indicator since it is comparing two consecutive samples of the data 131.

The signal 138 and the signal 136 can be combined together, if required, to form a signal having three different states: one indicating that the data 131 is leading the clock 134; one indicating that the data 131 is lagging the clock 134; and one indicating that the data 131 has a missing transition. The propagation delay of the XOR gate 141 should closely match the clock to data output propagation delay of the M-DETDFF 121 in order to synchronize the data transition detection with the phase comparison.

Second Embodiment

FIG. 2 illustrates the structure of a PD 200 according to the second embodiment of the present invention. The PD 200 includes a plurality (e.g., preferably three) of Edge-Triggered Data Flip-Flops (ETDFF) 211, 212 and 213 and a Modified Double-Edge-Triggered Data Flip-Flop (M-DETDFF) 221. M-DETDFF 221 's operation is described below and an example of such a circuit is given in FIG. 3.

A signal 231 is received in the input D of a first ETDFF 211 and in the input D of a second ETDFF 212. A first clock signal 232 is applied to the clock input C of the first ETDFF 211, thereby sampling the signal 231. A second clock signal 234 is applied to the clock input C of the second ETDFF 212, thereby sampling the signal 231. The signal 233 present at the output Q of the first ETDFF 211 is applied to the input D of a third ETDFF 213. The first clock signal 232 is also applied to the clock input C of the third ETDFF 213, thereby sampling the signal 233.

The signal 235 present at the output Q of the second ETDFF 212 is applied to the input D of a M-DETDFF 221. The signal 238 is applied to the clock input C of the M-DETDFF 221, thereby sampling the signal 235. The signal 238 results from the subtraction of the signal 237, present at the output Q of the third ETDFF 213, from the signal 233, present at the output Q of the first ETDFF 211 according to the logical operation depicted in FIG. 2B. The subtraction signal 238 is easily obtained by providing signals 233 and 237 as inputs into a differential amplifier (not shown in FIG. 2A).

PD 200 is optimized to be preferably used in a receiver of a transmission system to recover the clock signals 232 and 234 from the signal 231 using the phase-locked loop technique. The signal 231 is, in this case, a random data stream. In the rest of the description, the signal 231 refers to a random data stream which is preferably NRZ (Non-Return-to-Zero) coded and will be referred to as data 231. It is noted that PD 200 is optimized if the clock signals 232 and 234 have preferably exactly the same frequency, the clock signal 234 being preferably half a data 231 bit time late compared to the clock signal 232. The data 231 bit time is equal to half of the smallest period present in the signal. The rate of data 231 is equal to the inverse of a bit time.

It is also noted that PD 200, when used for clock recovery applications from NRZ random data, is optimized with either the frequency of the clock signals 232 and 234 equal to the rate of data 231 or the frequency of the clock 232 and 234 equal to half the rate of data 231.

When the frequency of the clock signals 232 and 234 is to be equal to the rate of the data 231, then the following conditions should apply: ETDFFs 211, 212 and 213 are preferably single-edge triggered data flip-flops, e.g., all of them are triggered only on either positive or negative edges of the clock signals 232 and 234, respectively. Phase detector 200 is then known as a “full-rate PD”. When the frequency of the clock signals 232 and 234 is to be equal to half the rate of data 231, then the following conditions should apply: ETDFFs 211, 212 and 213 are preferably double-edge triggered data flip-flop, e.g., all of them are triggered on both positive and negative edges of the clock signals 232 and 234, respectively. Phase detector 200 is then known as a “half-rate PD”.

The signals 233 and 235 are samples of the data 231 shifted from one another by half a bit time in one or the other direction depending on the position of the sampling edges (e.g., the edges used to trigger ETDFF 212) of the clock signal 234 with respect to the edges of the data 231. The signal 237 is also identical to the signal 233 but ahead in time by one bit time. Consequently, the signal 238, obtained from the logical subtraction of the signal 237 from the signal 233 according to Table I, toggles between +1 and −1 states each time a transition is present in the data 231, and is equal to zero when a transition is missing.

The M-DETDFF 221 transfers the signal 235 to its output Q, which is the signal 236, on one edge of the signal 238 and the complement of the signal 235 to its output Q, which is the signal 236, on the other edge of the signal 238. Thus, each time a data transition occurs, the M-DETDFF 221 senses the sign of the shift between the signal 233, and the signal 235 (e.g., the M-DETDFF will sense if the signal 233 is leading or lagging the signal 235) and its output 236 will be either equal to state “+1” or state “−1”. Whenever a data transition is missing, then the signal 238 transitions to state “0”. Consequently, the output 236 also transitions to state “0” and remains equal to state “0” until the next data transition happens.

When the PD 200 is used for clock and data recovery applications using the phase-locked loop technique, then under locked conditions, the edges of the clock 234 which are used to trigger the ETDFF 212 are aligned with the edges of the data 231. Consequently, the edges of the clock 232 which are used to trigger the ETDFF 211 and ETDFF 213 are aligned at the midpoint of each bit interval of the data 231 and the data 231 can thus be recovered.

FIG. 3 is an example of a Double-Edge-Triggered Data Flip-Flop (DETDFF). The data signal 331 to be sampled is received in the input D of a first latch 311 and in the input D of a second latch 312. The clock signal 332 is applied to the clock input C of the latch 311 and to the clock input C of the latch 312. The first latch and second latch sample the data 331 on opposite edges of the clock signal 332 (the circle sign present at the clock input of the second latch represents that the first and second latch are sampling the data on opposite edges). The frequency of the clock signal 332 is equal to half the data 331 rate.

The signal 333 present at the output Q of the latch 311 is applied to the data input D1 of a selector 321. The signal 334 present at the output Q of the latch 312 is applied to the data input D2 of the selector 321. The clock signal 332 is applied to the clock input C of the selector 321. The selector 321 always selects the output Q of the latch which is in the hold mode (e.g., the signal 333 present at the output Q of the latch 311 is transferred to the output Q of the selector 321 when the latch 311 is in the hold mode and the signal 334 present at the output Q of the latch 312 is transferred to the output Q of the selector 321 when the latch 312 is in the hold mode). Consequently, the data 331 is transferred to the output Q of the DETDFF 300 on every transition of the clock signal 332 (e.g., on positive and negative edges of the clock signal 332).

FIG. 4 is an example of a Modified Double-Edge-Triggered Data Flip-Flop (M-DETDFF). The data signal 431 to be sampled is received in the input D of a first latch 411 and in the input D of a second latch 412. The clock signal 432 is applied to the clock input C of the latch 411 and to the clock input C of the latch 412. The first latch and second latch sample the data 431 on opposite edges of the clock signal 432 (the circle sign present at the clock input of the second latch represents that the first and second latch are sampling the data on opposite edges). The frequency of the clock signal 432 is equal to half the data 431 rate.

The signal 433 present at the complement output Q of the latch 411 (the circle sign present at the data output Q of the first latch represent the complement output) is applied to the data input D1 of a selector 421. The signal 434 present at the output Q of the latch 412 is applied to the data input D2 of the selector 421. The clock signal 432 is applied to the clock input C of the selector 421. The selector 421 always selects the output Q of the latch which is in the hold mode (e.g., the signal 433 present at the complementary output Q of the latch 411 is transferred to the output Q of the selector 421 when the latch 411 is in the hold mode and the signal 434 present at the output Q of the latch 412 is transferred to the output Q of the selector 421 when the latch 412 is in the hold mode). Consequently, the data 431 is transferred to the output Q of the M-DETDFF 400 on one edge (e.g., positive or negative edge) of the clock signal 432, and the complement of data 431 is transferred to the output Q of the M-DETDFF 400 on the other edge (e.g., negative or positive edge) of the clock signal 432.

Third Embodiment

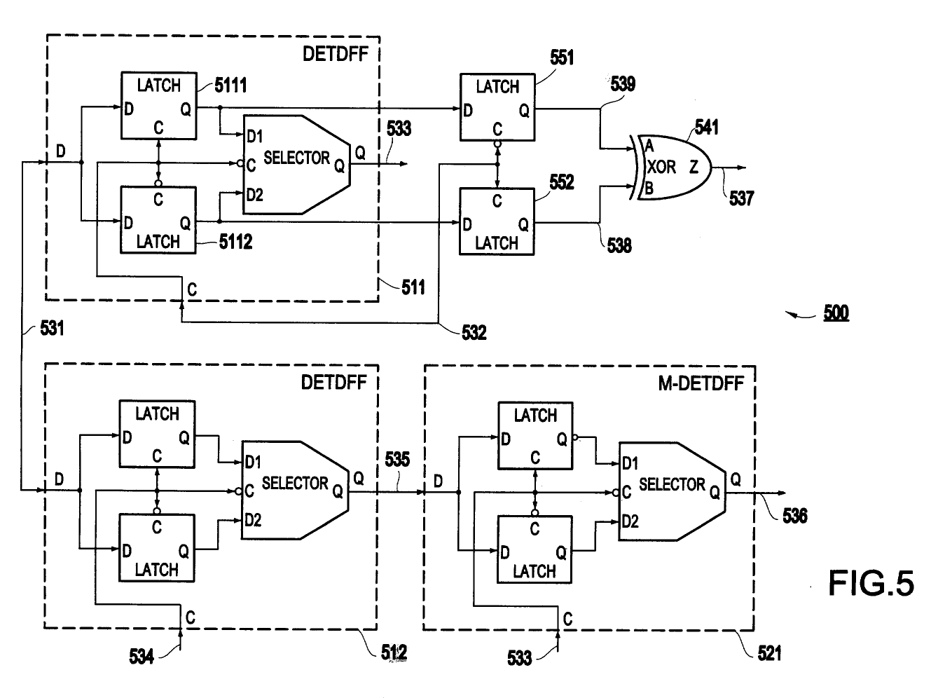

FIG. 5 illustrates the structure of a half-rate PD 500 according to the third embodiment of the present invention. The half-rate PD 500 includes a plurality (e.g., preferably two) of Double-Edge-Triggered Data Flip-Flops (DETDFF) 511 and 512 (as described in FIG. 3), a two-input XOR gate 541, two latches 551 and 552 and a Modified Double-Edge-Triggered Data Flip-Flop (M-DETDFF) 521, as described in FIG. 4.

A signal 531 is received in the input D of a first ETDFF 511 and in the input D of a second ETDFF 512. A first clock signal 532 is applied to the clock input C of the first ETDFF 511, thereby sampling the signal 531. A second clock signal 534 is applied to the clock input C of the second ETDFF 512, thereby sampling the signal 531. The signal 535 present at the output Q of the second ETDFF 512 is applied to the input D of the M-DETDFF 521. The signal 533 present at the output Q of the first ETDFF 511 is applied to the clock input C of the M-DETDFF 521, thereby sampling the signal 535. The signal present at the output Q of the latch 5111 is applied to the data input D of a first latch 551. The signal present at the output Q of latch 5112 is applied to the data input D of a second latch 552.

The clock signal 532 is applied to the clock input C of the latch 551. Latch 551 and latch 5111 are triggered on opposite edges. The clock signal 532 is applied to the clock input C of the latch 552. Latch 552 and latch 5112 are triggered on opposite edges. The signal 539 present at the output Q of latch 551, and the signal 538 present at the output Q of latch 552 are applied to the input A and B, respectively, of a XOR gate 541.

PD 500 is optimized to be preferably used in a receiver of a transmission system to recover the clock signals 532 and 534 from the signal 531 using the phase-locked loop technique. The signal 531 is in this case a random data stream. In the rest of the description, the signal 531 refers to a random data stream which is preferably NRZ (Non-Return-to-Zero) coded and will be referred to as data 531. It is noted that PD 500 is optimized if the clock signals 532 and 534 have preferably exactly the same frequency, the clock signal 534 being half a data 531 bit time late compared to the clock signal 532. The data 531 bit time is equal to half the smallest period present in the signal. The rate of data 531 is equal to the inverse of a bit time.

It is also noted that PD 500, when used for clock recovery applications from NRZ random data, is optimized with the frequency of the clock 532 and 534 equal to half the rate of data 531.

The signals 533 and 535 are samples of the data 531 shifted from one another by half a bit time in one or the other direction depending on the position of the sampling edges (e.g., the edges used to trigger DETDFF 512) of the clock signal 534 with respect to the edges of the data 531. The M-DETDFF 521 senses the sign of this shift (e.g., the M-DETDFF will sense if the signal 533 is leading or lagging the signal 535). Indeed, the M-DETDFF 521 transfers the signal 535 to its output Q, which is the signal 536, on one edge of the signal 533 and the complement of the signal 535 to its output Q, which is the signal 536, on the other edge of the signal 533. Thus the signal 536 present at the output Q of the M-DETDFF 521 is a binary signal which state indicates whether the clock signal 534 is leading or lagging the data 531.

When the PD 500 is used for clock and data recovery applications using the phase-locked loop technique, then under locked conditions, the edges of the clock 534 which are used to trigger the DETDFF 512 are aligned with the edges of the data 531. Consequently, the edges of the clock 532 which are used to trigger the DETDFF 511 are aligned at the midpoint of each bit interval of the data 531 and the data 531 can thus be recovered.

The signal 539 and the signal 538 correspond to the even and odd data of data 531 (e.g., the signal 539 and the signal 538 correspond to the demultiplexed data of data 531) and are shifted from one another by a data 531 bit time. Consequently, the binary signal 537 present at the output Z of the XOR gate 541 is then a data transition indicator since it is comparing two consecutive samples of the data 531.

The signal 537 and the signal 536 can be combined together, if required, to form a signal having three different states: one indicating that the data 531 is leading the clock 534; one indicating that the data 531 is lagging the clock 534; and one indicating that the data 531 has a missing transition. The propagation delay of the XOR gate 541 should closely match the clock to data output propagation delay of the M-DETDFF 521 in order to synchronize the data transition detection with the phase comparison.

The phase detector of the present invention can be used in any application which requires to compare the position of the edges of any given signal with the position of the edges of a clock signal. With the phase detector of the present invention, a bang-bang (or early/late) type of operationn is achieved, thus enabling higher operating frequency and a smaller static phase error (as opposed to linear Pds). A self-correcting operation to accommodate process, temperature and power supply variation and aging is also achieved by the present invention.

The present invention also has a retiming function as part of its operation, for optimum clock and data alignment. The present invention also has a tri-state output to accommodate long run length random data, to enable robust locking behavior and reduced jitter generation. It also possesses a short latency to reduce the jitter generation.

The present invention has a very simple architecture to minimize power consumption, enable straightforward data and clock distribution, and enable a compact layout design, the latter two features thereby allowing a high speed operation. It presents a versatile architecture that can be easily adapted for full-rate and half-rate clocking, without a major increase in either complexity or power consumption.

While the invention has been described in terms of a single preferred embodiment, those skilled in the art will recognize that the invention can be practiced with modification within the spirit and scope of the appended claims.

Having thus described our invention, what we claim as new and desire to secure by Letters Patent is as follows:

1. A phase detector, comprising:
a first flip-flop for sampling an incoming data signal in accordance with a first local clock signal to produce a first sampled data signal;
a second flip-flop for sampling said incoming data signal in accordance with a second local clock signal to produce a second sampled data signal; and
a third flip-flop for sampling said second sampled data signal based on said first sampled data signal to produce a binary control signal, said third flip-flop comprising a double-edge flip-flop.

2. The phase detector of claim 1, wherein said binary control signal comprises an early-late control signal representing whether edges of the first local clock signal are early or late with respect to transitions of the incoming data signal.

3. The phase detector of claim 1, wherein said first flip-flop and said second flip-flop each comprise a single-edge-triggered flip-flop.

4. The phase detector of claim 3, wherein said phase detector comprises a full-rate phase detector.

5. The phase detector of claim 1, wherein said first flip-flop and said second flip-flop each comprise a double-edge-triggered flip-flop.

6. The phase detector of claim 5, wherein said phase detector comprises a half-rate phase detector.

7. The phase detector of claim 1, wherein said third flip-flop comprises a modified double-edge flip-flop.

8. The phase detector of claim 7, wherein said modified double-edge-triggered flip-flop comprises a flip-flop in which an output on a first sampling edge comprises an input into said flip-flop at the time of said first sampling edge and said output on a next sampling edge comprises a complement of an input into said flip-flop at the time of said second sampling edge

9. The phase detector of claim 1, further comprising:
a fourth edge-triggered flip-flop for sampling said first sampled data in accordance with said first local clock signal to produce a third sampled data signal.

10. The phase detector of claim 9, further comprising:
an XOR gate for receiving said first sampled data and said third sampled data as inputs and for providing as an output a signal representing a transition detection.

11. The phase detector of claim 9, further comprising:
a subtractor for receiving said first sampled data and said third sampled data as inputs and for providing as an output a signal representing a transition detection.

12. The phase detector of claim 11, wherein said subtractor comprises a differential amplifier.

13. The phase detector of claim 6, wherein said first flip-flop further provides a third sampled signal and a fourth sampled signal, said phase detector further comprising:
a first latch for receiving said third sampled signal; and
a second latch receiving said fourth sampled signal.

14. The phase detector of claim 13, further comprising:
an XOR gate for receiving as input signals an output signal from said first latch and an output signal from said second latch, said XOR gate providing a signal representing a transition detection.

15. The phase detector of claim 1, further comprising:
calculator for calculating a transition detection using said first sampled signal.

16. The phase detector of claim 15, wherein said calculator comprises an XOR gate.

17. The phase detector of claim 15, wherein said calculator comprises a subtraction circuit.

18. The phase detector of claim 15, said calculator further comprising:
a flip-flop for sampling said first sampled signal to derive a second input signal used in said calculator.

19. The phase detector of claim 9, wherein said fourth edge-triggered flip-flop comprises a single edge-triggered flip-flop for a full-rate phase detector and a double edge-triggered flip-flop for a half-rate phase detector.

20. A receiver, comprising:
the phase detector of claim 1.

21. A communication system, comprising:
the phase detector of claim 1.

22. A method of data/clock recovery, comprising:
sampling an incoming data signal in accordance with a first local clock signal to produce a first sampled data signal, said first sampled data signal to be used to calculate a transition detection; and
sampling said incoming data signal in accordance with a second local clock signal to produce a second sampled data signal, said second sampled data signal being used to derive an early/late control signal,
wherein said early/late control signal is derived using a double-edge flip-flop that samples said second sampled data signal in accordance with a clocking signal derived from said first sampled signal.

23. The method of claim 22, wherein said transition detection is calculated by using said first sampled data signal to perform one of an XOR function and a subtraction function.

24. The method of claim 22, further comprising:
sampling said first sampled data signal to provide a second input signal for said transition detection calculation.

25. The method of claim 22, wherein said sampling to produce said first sampled data signal and said sampling to produce said second sampled data signal are each performed using a single-edge-triggered flip-flop.

26. The method of claim 25, wherein said data/clock recovery comprises a full-rate recovery.

27. The method of claim 22, wherein said sampling to produce said first sampled data signal and said sampling to produce said second sampled data signal are each performed using a double-edge-triggered flip-flop.

28. The method of claim 27, wherein said data/clock recovery comprises a half-rate recovery.

29. The method of claim 23, wherein performing said subtraction function comprises using a differential amplifier.

30. A circuit for regenerating a data signal and/or recovering a clock signal, said circuit comprising:
a first calculator for calculating a transition detection of an input data signal; and
a second calculator for calculating an early/late control signal, said second calculator including a modified double-edge-triggered flip-flop, said modified double-edge-triggered flip-flop comprising a flip-flop in which an output on a first sampling edge equals an input into said flip-flop at the time of said first sampling edge and said output on a next sampling edge equals a complement of an input into said flip-flop at the time of said second sampling edge.
